(19) United States
(12) Patent Application Publication
(10) Pub. No.: US 2026/0358718 A1
(43) Pub. Date: Nov. 12, 2026

(54) METHODS OF PERFORMING OPTICAL PROXIMITY CORRECTION AND RELATED SYSTEM

(71) Applicant: Taiwan Semiconductor Manufacturing Company Limited, Hsin-Chu (TW)

(72) Inventors: Jia-Guei JOU, New Taipei City (TW); Hsin-Lun TSENG, Taoyuan (TW); Shiuan-Li LIN, Kaohsiung City (TW); En-Chi HSU, Keelung City (TW)

(21) Appl. No.: 19/203,440

(22) Filed: May 9, 2025

(51) Int. Cl. G03F 7/00

(52) U.S. Cl. CPC G03F 7/70441

(57) ABSTRACT

A method is provided. The method includes: receiving first circuit layout data associated with a material layer of an integrated circuit (IC) device; receiving second circuit layout data associated with the material layer; generating comparison layout data by performing a logical operation on the first circuit layout data and the second circuit layout data; determining a changed region of the second circuit layout data based on the comparison layout data; receiving first optically-corrected layout data associated with the first circuit layout data; generating second optically-corrected layout data by optically correcting the changed region; and generating third circuit layout data including the first optically-corrected layout data and the second optically-corrected layout data.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 1C illustrate diagrammatic views of a semiconductor wafer, a lithography system, and a method of forming a mask that includes performing optical proximity correction (OPC), in accordance with some embodiments.

FIG. 2 illustrates a diagrammatic view of a method of performing OPC, in accordance with some embodiments.

FIGS. 3A, 3B, 3C, 3D, and 3E illustrate diagrammatic views of a method of forming a mask that includes performing optical proximity correction (OPC), in accordance with some embodiments.

FIG. 4 is a flow diagram illustrating a method of forming an integrated circuit device, in accordance with some embodiments.

FIG. 5 is a flow diagram illustrating a method of forming an integrated circuit device, in accordance with some embodiments.

FIG. 6 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature’s relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, in semiconductor mask preparation, a new tapeout (NTO) can refer to an initial tapeout that is associated with, for example, a first iteration or version of an integrated circuit (IC) device. A re-tapeout (RTO) can refer to a second or later iteration or version of the IC device, in which the RTO typically includes minor design changes to the NTO. In mask preparation, optical proximity correction (OPC) is time-intensive and repeated OPC can affect mask/wafer uniformity, such as smallest dimension uniformity (CDU). For example, OPC may be performed on the full layout at both the NTO and RTO stages. As just mentioned, performing OPC on the fully layout can result in large consumption of time and power resources as well as uniformity degradation of circuit features in unchanged regions of the RTO.

In embodiments of the disclosure, changed regions of the RTO are determined. The changed regions can be regions of the RTO that are different than corresponding regions of the NTO. Determining the changed regions can include performing an exclusive-OR (XOR) logical operation on the RTO and the NTO. The OPC can be performed on the changed regions of the RTO, then the resulting corrected changed regions can replace corresponding regions in the NTO to generate an optically-corrected RTO.

In some embodiments, OPC is performed on a region-by-region basis, which can include a sequence of first, second, third and fourth regions that are arranged in a grid. Changed regions that are associated with the first, second and third regions can result in affected regions, such that the affected regions benefit from regenerated OPC based on the corrected changed regions. The OPC can be performed on the affected regions of the RTO, then the resulting corrected affected regions can replace corresponding regions in the NTO to generate the optically-corrected RTO. It should be understood that “NTO” includes the meaning of “optically-corrected NTO.”

Performing OPC on the changed regions and optionally on the affected regions of the RTO can reduce time and power resources consumed. Generating the optically-corrected RTO including original regions of the optically-corrected NTO can improve CDU by reducing degradation that results from repeated OPC operations performed on unchanged regions.

In some embodiments, OPC is performed on a second layout based on a first layout. The second layout can be an RTO layout. The first layout can be an NTO layout or a prior RTO layout. Namely, the method can include generating an optically-corrected RTO that includes corrected change regions of the RTO layout and original regions of the NTO layout or of the prior RTO layout. For example, an optically-corrected RTO layout of a third version or iteration of an IC device can include second optically-corrected changed regions and optionally second optically-corrected affected regions of the RTO layout, first optically-corrected changed regions and optionally first optically-corrected affected regions of the prior RTO layout and original regions of the NTO layout.

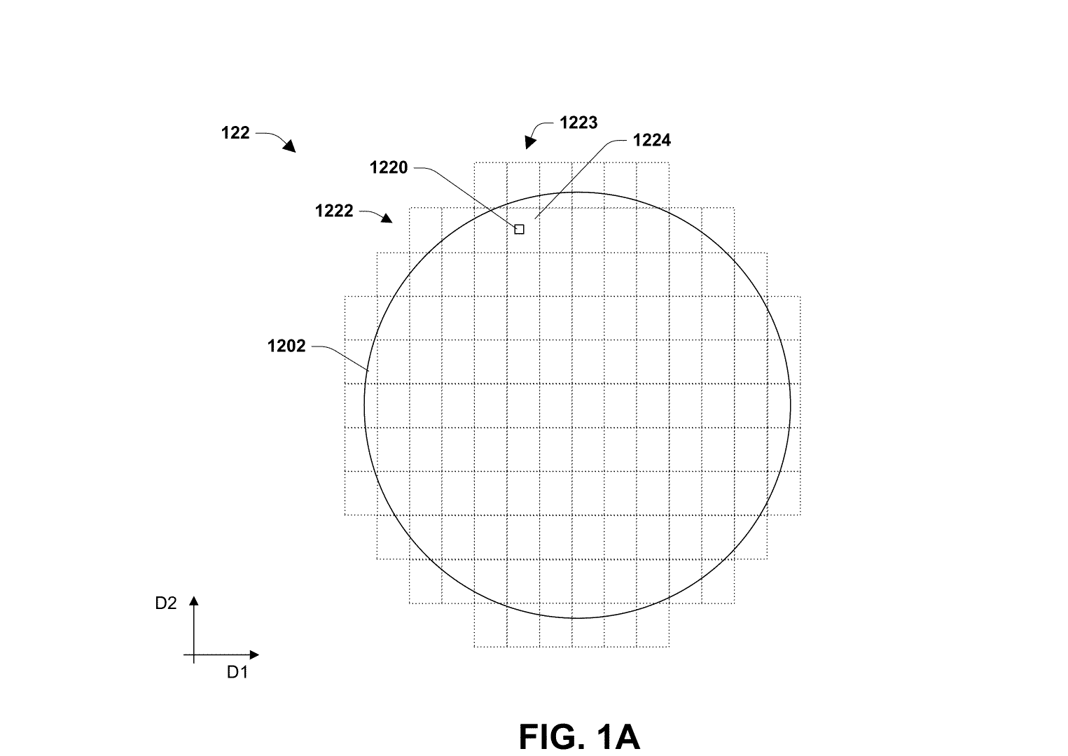

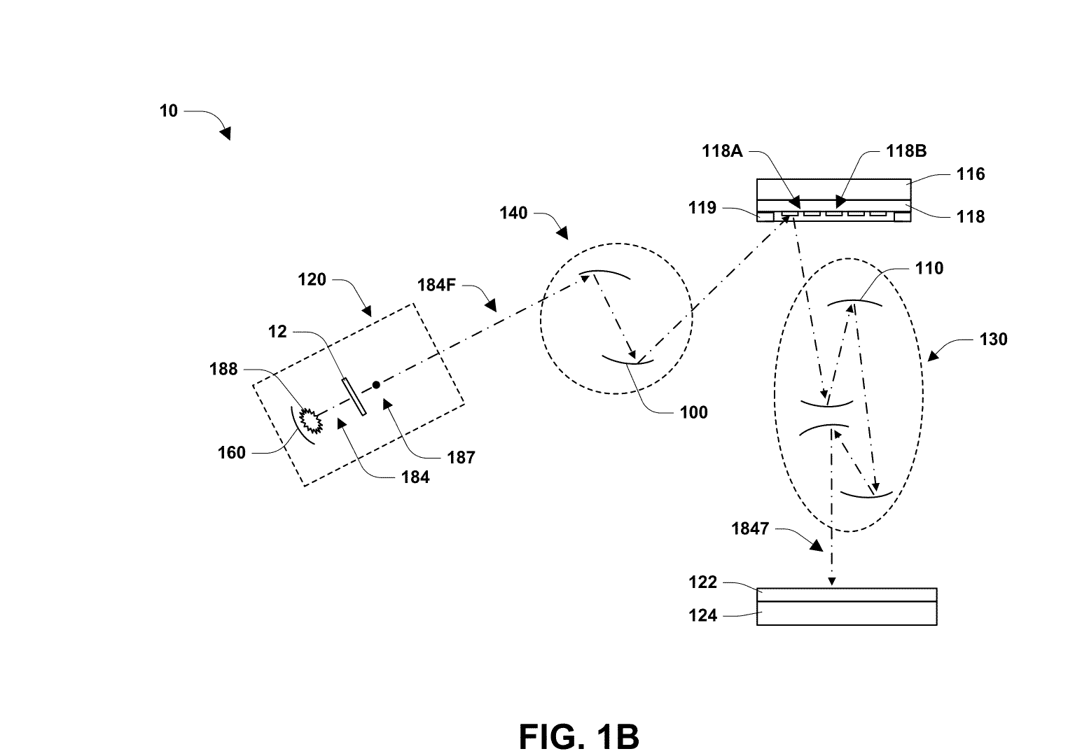

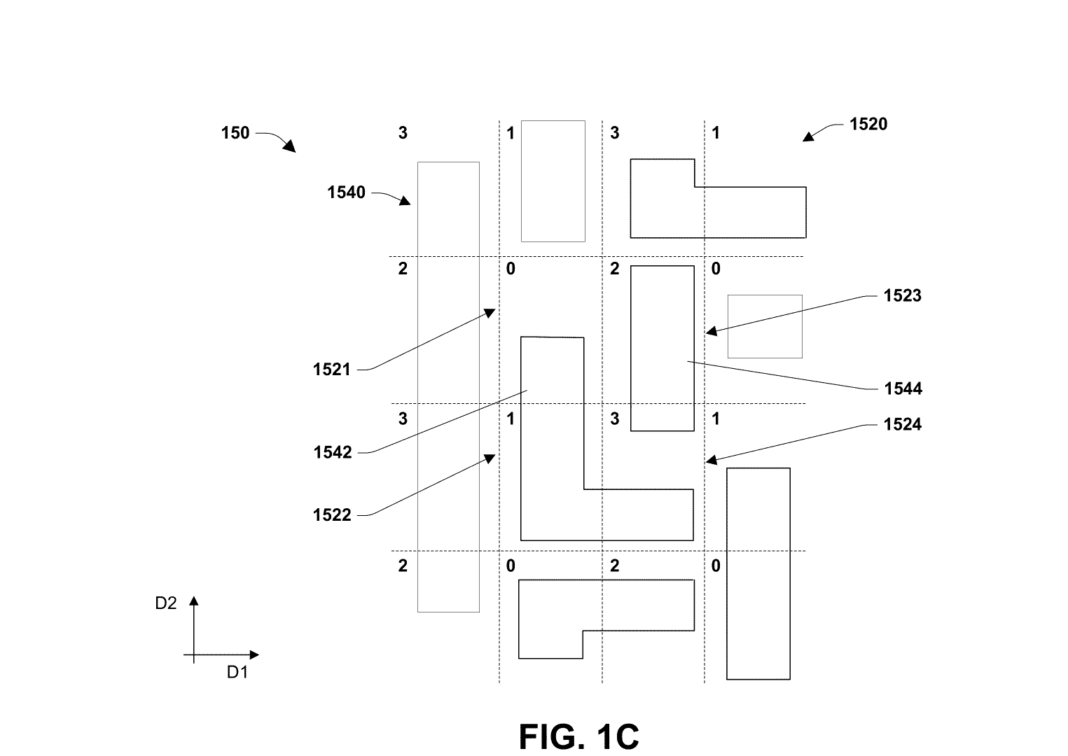

FIGS. 1A, 1B, and 1C illustrate intermediate diagrammatic views of a method of forming an integrated circuit device, in accordance with some embodiments.

In FIG. 1A, an in-process IC wafer 122 (or simply “the first wafer 122”) is provided. The in-process IC wafer 122 can include an integrated circuit die region 1220 positioned on and/or in a semiconductor substrate 1202. In some embodiments, the in-process IC wafer 122 is formed by process operations, which can include patterning, deposition, cleaning, planarizing, annealing, epitaxial growing, and the like. The process operations form circuit features, such as metal gates, epitaxial source/drains, conductive vias, conductive traces, and the like.

In some embodiments, the semiconductor substrate 1202 comprises at least one of a substrate, a photomask, a semiconductor device, a dielectric layer, an epitaxial layer, a silicon-on-insulator (SOI) structure, a semiconductor layer, a conductive material layer, a die, etc. The semiconductor substrate 1202 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor substrate 1202 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor substrate 1202 are within the scope of the present disclosure.

In some embodiments, the IC die regions 1220 can be in-process dies or completed dies that are to be singulated in a subsequent process operation. The IC die regions 1220 can be or include microcontrollers (MCUs), microprocessors (MPUs), graphics processing units (GPUs), artificial intelligence (AI) accelerators, memory ICs, analog ICs, logic ICs, optoelectronics, power management ICs, wireless communication ICs, image sensor ICs, image processing ICs, or the like. In some embodiments, the IC die regions 1220 are arranged in one or more rows 1222 and one or more columns 1223. The rows 1222 extend along a first direction D1 and are arranged along a second direction D2. The columns 1223 extend along the second direction D2 and are arranged along the first direction D1. Each of the IC die regions 1220 may be positioned in a photolithography field 1224 that has size associated with a single exposure “shot” from a mask. The photolithography field 1224 may include at least two IC die regions 1220. For example, the photolithography field 1224 may have dimensions of about 26 mm x 33 mm and each of the IC die regions 1220 may have dimensions of about 10 mm x 10 mm or smaller. Other dimensions for the IC die regions 1220 are also contemplated as embodiments herein.

In some embodiments, each of the IC die regions 1220 includes one or more patterned layers of different materials that are arranged to form electronic circuits. Components of each IC die region 1220 of the IC die regions 1220 can include transistors, interconnects, capacitors, resistors, inductors, photodiodes, color filters and the like. The IC die region 1220 can include many material layers, such as the semiconductor substrate 1202, epitaxial layers, isolation layers, gate dielectric layers, gate electrode layers, source/drain layers, contact layers, interconnect layers, dielectric layers, passivation layers and the like. Formation of the material layers can include performing one or more semiconductor processes, such as deposition, photolithography, etching/patterning, doping/implantation, planarization and the like. Along a vertical axis that is perpendicular to the major surface of the IC die region 1220, from bottom to top, the IC die region 1220 can include a device region and an interconnect region on the device region. The device region can generally include the transistors and capacitors, and the interconnect region can generally include the interconnects as well as capacitors, inductors, resistors and the like. The transistors can be or include field effect transistors (FETs), which can include planar transistors, fin FETs (or “FinFETs”), nanostructure FETs (e.g., nanosheet FETs or the like), vertical FETs, and the like. In some embodiments, the interconnect region can include memory devices, such as phase-change random access memory (PCRAM) devices, magnetoresistive random access memory (MRAM) devices, and/or other suitable memory devices.

In many IC device products, revision of a design of the IC device product may be performed to increase reliability, performance, and the like. The revision of the design can include making changes to a layout of one or more layers of the IC device product. For example, the layout may be revised by changing dimensions of a circuit feature, such as a source/drain or interconnect, deleting the circuit feature, adding the circuit feature where it was not present in a previous version, or the like. Throughout the description, reference can be made to a new tapeout (NTO) and a retapeout (RTO). The NTO can refer to a first layout associated with the IC device product, and the RTO can refer to a second layout that is a revision of the first layout. The NTO can be associated with a first mask or set of first masks. The RTO can be associated with a second mask or set of second masks. The first mask(s) are different than the second mask(s). To fabricate the IC device product according to the NTO, the photolithography field 1224 can be generated by the first mask(s). To fabricate the IC device product according to the RTO, the photolithography field 1224 can be generated by the second mask(s).

In advanced semiconductor manufacturing nodes, each mask that is used to generate patterned light associated with the photolithography field 1224 can be formed based on an optically-corrected layout. To generate the optically-corrected layout, the first layout or the second layout can be optically corrected by performing optical proximity correction (OPC).

OPC is a technique used in semiconductor manufacturing that can improve accuracy of patterns formed on a silicon wafer, such as the semiconductor substrate 1202, during photolithography. In photolithography, a mask reflects light from a light source according to a mask pattern onto a photoresist-coated wafer (e.g., the semiconductor substrate 1202) to define features of integrated circuits. Due to limitations of light diffraction and other optical effects, the reflected image can become distorted, especially as feature sizes shrink below the wavelength of the light used.

OPC compensates for distortions by pre-adjusting the mask pattern. OPC can involve modifying shapes and edges of mask features, which can include adding or subtracting small geometric corrections, such as serifs, notches, or scattering bars, so that the final pattern on the wafer more closely matches the intended design. These adjustments can account for factors that include light interference, proximity effects (where nearby features influence each other), and process variations. OPC can be implemented using software that simulates the lithography process and iteratively refines the mask design. OPC is beneficial for achieving precision in modern chip manufacturing, enabling the production of smaller, denser, and more reliable semiconductor devices.

FIG. 1B illustrates a schematic view of a system 10, in accordance with some embodiments. In some embodiments, the system 10 is a lithography system, such as a lithography exposure system, and can be referred to as the lithography system 10 or the lithography exposure system 10. In some embodiments, the system 10 is a semiconductor processing tool, and can be referred to as the semiconductor processing tool 10. The system 10 is described to provide context for understanding the embodiments.

In some embodiments, the system 10 is an extreme ultraviolet (EUV) lithography system designed to expose a resist layer by EUV radiation. The system 10 includes a light source 120, an illuminator 140, a mask stage 116, a projection optics module (or projection optics box (POB)) 130 and a substrate stage 124, in accordance with some embodiments. The elements of the system 10 can be added to or omitted, and the disclosure should not be limited by the embodiment. Some elements of the system 10 may be rearranged in other embodiments. For example, position of a collector 160 relative to the illuminator 140 may be different than that depicted in FIG. 1B.

The light source 120 is configured to generate light radiation 184 (or “first light 184”) having a wavelength ranging between about 1 nm and about 100 nm in certain embodiments. In one particular example, the light source 120 generates a EUV light radiation 184 with a wavelength centered at about or substantially at 13.5 nm. Accordingly, the light source 120 is also referred to as a EUV radiation source. However, it should be appreciated that the light source 120 should not be limited to emitting EUV light radiation 184. The light source 120 can be utilized to perform any high-intensity photon emission from excited target fuel.

In some embodiments, the light source 120 includes a droplet generator that delivers a target fuel to a zone of excitation at which at least one laser pulse from a laser generator hits the droplets. In an embodiment, the target fuel includes tin (Sn). The laser generator is configured to generate at least one laser pulse to allow the conversion of the droplets into plasma 188. In some embodiments, the laser generator is configured to produce a laser pulse to a lighting point to convert the droplets to plasma 188 which generates EUV light radiation 184. The laser pulse can be directed through a window (or lens), and irradiate droplets at the lighting point.

The plasma 188 emits the EUV light radiation 184, which is collected by the collector 160 and directed toward the illuminator 140. The collector 160 reflects and focuses the EUV light radiation 184 for the lithography processes performed through an exposure tool, such as the system 10. In some embodiments, the collector 160 is in a different chamber than the light source. For example, the collector 160 may be positioned in a chamber between the plasma 188 and the illuminator 140.

In some embodiments, the laser generator is a carbon dioxide (CO2) laser source. In some embodiments, the laser generator is used to generate the laser pulse with single wavelength. The laser pulse can be transmitted through an optic assembly for focusing and determining incident angle of the laser pulse. In some embodiments, the laser pulse has a spot size of about 200-300 μm, such as 225 μm. The laser pulse is generated to have certain driving power to meet wafer production targets, such as a throughput of 125 wafers per hour (WPH), though greater WPH may be achieved. In some embodiments, the laser pulse is equipped with about 23 kW driving power. In various embodiments, the driving power of the laser pulse is at least 20 kW, such as 27 kW.

In various embodiments, the illuminator 140 includes various refractive or reflective optic components, such as a single lens or a lens system having multiple reflectors or mirrors 100, for example lenses (zone plates) or alternatively reflective optics (for EUV lithography exposure system), such as a single mirror or a mirror system having multiple mirrors in order to direct light from the light source 120 onto the mask stage 116, particularly to a mask 118 secured on the mask stage 116. In the present embodiment where the light source 120 generates light in the EUV wavelength range, reflective optics are employed. In some embodiments, the illuminator 140 includes at least three lenses.

The mask stage 116 is configured to secure the mask 118. In some embodiments, the mask stage 116 includes an electrostatic chuck (e-chuck) to secure the mask 118. This is because gas molecules absorb EUV radiation and the lithography exposure system for the EUV lithography patterning is maintained in a vacuum environment to avoid EUV intensity loss. In the present disclosure, the terms mask, photomask, and reticle are used interchangeably. In the present embodiment, the mask 118 is a reflective mask. One exemplary structure of the mask 118 includes a substrate with a suitable material, such as a low thermal expansion material (LTEM) or fused quartz. In various examples, the LTEM includes TiO₂ doped SiO₂, or other suitable materials with low thermal expansion. The mask 118 includes a reflective multilayer deposited on the substrate. The mask 118 has a pellicle assembly 119 mounted thereto, which is beneficial to reduce settling of particles on the mask 118.

As described with reference to FIG. 1A, the mask 118 has a pattern therein that is associated with a circuit layout, such as an NTO layout or an RTO layout. A mask layout that is used during formation of the pattern of the mask 118 is an optically-corrected layout, which can be formed by performing OPC on the NTO layout or the RTO layout. In embodiments of the disclosure, a method of performing OPC on the RTO layout can reduce time for generating the mask layout based on the RTO layout, which reduces use of processing resources and saves power. In the embodiments, the OPC performed on the RTO layout is targeted to change regions and affected regions that are adjacent to the change regions. As such, the finished RTO layout includes unchanged regions directly imported from the NTO layout and regenerated regions that are based on the change regions and the affected regions. Using the unchanged regions directly obtained from the NTO layout reduces degradation of smallest dimension uniformity or “CDU.” For example, performing OPC multiple times on the same layout can result in repeated adjustments or iterations of the OPC process introducing inconsistencies or errors. For example, over-correction, cumulative rounding errors in the mask design, or interactions with process variation can cause the smallest dimensions to vary more than is beneficial across the mask or wafer, degrading the uniformity and potentially affecting chip performance or yield.

The projection optics module (or projection optics box (POB)) 130 is configured for imaging the pattern of the mask 118 on to the in-process IC wafer 122 secured on the substrate stage 124 of the system 10. In some embodiments, the POB 130 has refractive optics (such as for a UV lithography exposure system) or alternatively reflective optics (such as for a EUV lithography exposure system) in various embodiments, e.g., optics 110. The light directed from the mask 118, carrying the image of the pattern defined on the mask, is collected by the POB 130. The POB 130 directs light 1847 carrying the pattern onto the in-process IC wafer 122, such as onto a photosensitive layer (e.g., a resist layer) that is coated on a surface of the in-process IC wafer 122 that faces the POB 130. The illuminator 140 and the POB 130 are collectively referred to as an optical module of the system 10. In some embodiments, the POB 130 includes at least five reflective optics.

As a result, the mask 118 can include first pattern regions 118A that are associated with an NTO layout and second pattern regions 118B that are associated with an RTO layout. For example, the mask 118 may be formed by generating third circuit layout data that is based on first circuit layout data (e.g., from the NTO layout) and second circuit layout data (e.g., from the RTO layout). The first circuit layout data may be optically corrected to form first optically-corrected layout data, and the second circuit layout data may be selectively optically corrected to form second optically-corrected layout data. For example, changed regions of the second circuit layout data compared to the first circuit layout data may be optically corrected to form the second optically-corrected layout data. Generally, first size of the first optically-corrected layout data exceeds second size of the second optically-corrected layout data. For example, the first optically-corrected layout data may correspond to the entire NTO layout, and the second optically-corrected layout data may correspond to the changed region(s) of the RTO layout. A portion of the first optically-corrected layout data associated with the changed region may be removed and replaced by the second optically-corrected layout data. The replacement may include deleting the portion of the first optically-corrected layout data, then inserting the second optically-corrected layout data at a position of the portion. The mask 118 is then formed based on the third circuit layout data that includes the first optically-corrected layout data and the second optically-corrected layout data that replaces the portion of the first optically-corrected layout data associated with the changed region. The first pattern regions 118A can be formed based on the first optically-corrected layout data, and the second pattern regions 118B can be formed based on the second optically-corrected layout data. As such, the mask 118 can include first pattern regions 118A that are based directly on the NTO layout (e.g., a first version of an IC device) and second pattern regions 118B that are based directly on the RTO layout (e.g., a second version of the IC device) and optionally indirectly on the NTO layout.

The projection optics module (or projection optics box (POB)) 130 is configured for imaging the pattern of the mask 118 on to the in-process IC wafer 122 secured on the substrate stage 124 of the system 10. In some embodiments, the POB 130 has refractive optics (such as for a UV lithography exposure system) or alternatively reflective optics (such as for a EUV lithography exposure system) in various embodiments, e.g., optics 110. The light directed from the mask 118, carrying the image of the pattern defined on the mask, is collected by the POB 130. The POB 130 directs light 1847 carrying the pattern onto the in-process IC wafer 122, such as onto a photosensitive layer (e.g., a resist layer) that is coated on a surface of the in-process IC wafer 122 that faces the POB 130. The illuminator 140 and the POB 130 are collectively referred to as an optical module of the system 10. In some embodiments, the POB 130 includes at least five reflective optics.

In some embodiments, the in-process IC wafer 122 is made of silicon or other semiconductor materials. Alternatively, or additionally, the in-process IC wafer 122 may include other elementary semiconductor materials such as germanium (Ge). In some embodiments, the in-process IC wafer 122 is made of a compound semiconductor such as silicon carbide (SiC), gallium arsenic (GaAs), indium arsenide (InAs), or indium phosphide (InP). In some embodiments, the in-process IC wafer 122 is made of an alloy semiconductor such as silicon germanium (SiGe), silicon germanium carbide (SiGeC), gallium arsenic phosphide (GaAsP), or gallium indium phosphide (GaInP). In some other embodiments, the in-process IC wafer 122 may be a silicon-on-insulator (SOI) or a germanium-on-insulator (GOI) substrate.

In some embodiments, the system 10 is operable to perform one or more semiconductor manufacturing process operations on the in-process IC wafer 122. The in-process IC wafer (or simply “the wafer”) 122 comprises at least one of a substrate, a photomask, a semiconductor device, a dielectric layer, an epitaxial layer, a silicon-on-insulator (SOI) structure, a semiconductor layer, a conductive material layer, a die, etc. The in-process IC wafer 122 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The in-process IC wafer 122 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the in-process IC wafer 122 are within the scope of the present disclosure.

The in-process IC wafer 122 may have various device elements. Examples of device elements that are formed in the in-process IC wafer 122 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, the in-process IC wafer 122 is coated with a resist layer sensitive to the EUV radiation. Various components including those described above are integrated together and are operable to perform lithography processes.

The system 10 may include other modules or be integrated with (or be coupled with) other modules, such as a cleaning module designed to provide hydrogen gas to the light source 120. The hydrogen gas helps reduce contamination in the light source 120.

In some embodiments, the system 10 includes a filter assembly 12 between the plasma 188 and the illuminator 140. In operation, when EUV light radiation 184 that includes in-band light (e.g., EUV light) and OOB light is incident on the filter assembly 12, the filter assembly 12 can remove the OOB light while allowing the in-band light (e.g., EUV light) to pass through. Removing the OOB light is beneficial because heat from the OOB light, which can reside in the 100nm-800nm and >1000nm ranges, can degrade following mirrors, such as the collector mirror 160. Filtered light 184Fincluding the in-band light is generated by removing the OOB light from the EUV light radiation 184 by the filter assembly 12. In some embodiments, the filter assembly 12 is positioned between the plasma 188 and the collector mirror 160.

FIG. 1C illustrates a view of a method of performing OPC on a layout 150. The layout 150 can be an NTO layout, an RTO layout based on a previous NTO layout or previous RTO layout, or the like. The view of FIG. 1C depicts the layout 150 in graphical form. In some embodiments, the layout 150 is stored in memory of a system in a digital (e.g., binary) file format.

The layout 150 can be associated with a mask that is operable to reflect light according to a pattern of the layout 150. The layout 150 can include regions 1540 that can correspond to reflective regions of the mask. In some embodiments, the regions 1540 correspond to absorbing regions of the mask. Due to proximity effects, one or more of the regions 1540 may benefit from optical proximity correction (OPC). The OPC can modify shapes, edges and the like of the regions 1540, which can include adding or subtracting small geometric corrections, such as serifs, notches, or scattering bars, so that the final pattern reflected by the mask more closely matches an intended design. These adjustments can account for factors that include light interference, proximity effects (where nearby features influence each other), and process variations.

When performing OPC, correction regions 1520 can be defined that are associated with the layout 150. Each of the correction regions 1520 can have the same dimensions in a first direction D1 and a second direction D2. The correction regions 1520 can be arranged in rows along the first direction D1 and can be arranged in columns along the second direction D2. Each of the regions 1540 can be associated with one or more of the correction regions 1520.

A first correction region 1521, a second correction region 1522, a third correction region 1523 and a fourth correction region 1524 that are associated with a first region 1542 and a second region 1544 are described in detail with reference to FIG. 1C.

The first correction region 1521 is associated with a first sequence value labeled “0” in FIG. 1C. The second correction region 1522 is associated with a second sequence value labeled “1” in FIG. 1C. The third correction region 1523 is associated with a third sequence value labeled “2” in FIG. 1C. The fourth correction region 1524 is associated with a fourth sequence value labeled “3” in FIG. 1C.

In FIG. 1C, the first region 1542 is positioned in the first correction region 1521, the second correction region 1522 and the fourth correction region 1524. The second region 1544 is positioned in the third correction region 1523 and the fourth correction region 1524. It should be understood that positions and shapes of the regions 1540 including the first region 1542 and the second region 1544 depicted in FIG. 1C are examples. The regions 1540 may be arranged differently and have different shapes than depicted in FIG. 1C in accordance with various embodiments.

In an OPC operation, correction regions 1520 having the first sequence value “0” (e.g., the first correction region 1521) undergo optical proximity correction first, without referring to any immediately adjacent correction regions during OPC thereof. For example, OPC of the first correction region 1521 is performed only referring to the first correction region 1521 without referring to the second correction region 1522, the third correction region 1523 and the fourth correction region 1524. As described with reference to FIGS. 1A and 1B, the OPC can include modifying shapes and edges of the first region 1542 in the first correction region 1521, which can include adding or subtracting geometric corrections, such as serifs, notches, or scattering bars. In some embodiments, the OPC can include modifying (e.g., increasing or decreasing) width of the first region 1542 along the first direction D1, modifying (e.g., increasing or decreasing) length of the first region 1542 along the second direction D2, or both. Following OPC, the first correction region 1521 can be referred to as a “first corrected region.”

Following performing OPC on the first correction region 1521 and other correction regions 1520 having the first sequence value “0,” OPC can be performed on correction regions 1520 having the second sequence value “1,” such as the second correction region 1522. The OPC of the second correction region 1522 refers to the first corrected region(s). For example, as depicted in FIG. 1C, the second correction region 1522 is immediately adjacent a first corrected region on either side thereof along the second direction D2. The second correction region 1522 is immediately adjacent six “uncorrected regions,” which are correction regions 1520 that have not undergone OPC, such as the third correction region 1523 and the fourth correction region 1524. The OPC of the second correction region 1522 does not refer to the uncorrected regions immediately adjacent thereto.

Following performing OPC on the second correction region 1522 and other correction regions 1520 having the second sequence value “1,” OPC can be performed on correction regions 1520 having the third sequence value “2,” such as the third correction region 1523. The OPC of the third correction region 1523 refers to the first corrected region(s) and the second corrected region(s). For example, as depicted in FIG. 1C, the third correction region 1523 is immediately adjacent two corrected regions having the first sequence value “0” and four corrected regions having the second sequence value “1.” The third correction region 1523 is immediately adjacent two “uncorrected regions,” which are correction regions 1520 that have not undergone OPC, such as the fourth correction region 1524 and another correction region having the fourth sequence value “3.” The OPC of the third correction region 1523 does not refer to the uncorrected regions immediately adjacent thereto.

Following performing OPC on the third correction region 1523 and other correction regions 1520 having the third sequence value “2,” OPC can be performed on correction regions 1520 having the fourth sequence value “3,” such as the fourth correction region 1524. The OPC of the fourth correction region 1524 refers to the first corrected region(s), the second corrected region(s) and the third corrected region(s). For example, as depicted in FIG. 1C, the fourth correction region 1524 is immediately adjacent two corrected regions having the second sequence value “1,” two corrected regions having the third sequence value “2,” and four corrected regions having the first sequence value “0.” The fourth correction region 1524 is immediately adjacent only corrected regions and no “uncorrected regions.” As such, the OPC of the fourth correction region 1524 refers to corrected regions on all sides thereof. It should be understood that “all sides” includes the meaning of all sides in a single plane, such as right, left, top and bottom, and does not require front and back sides.

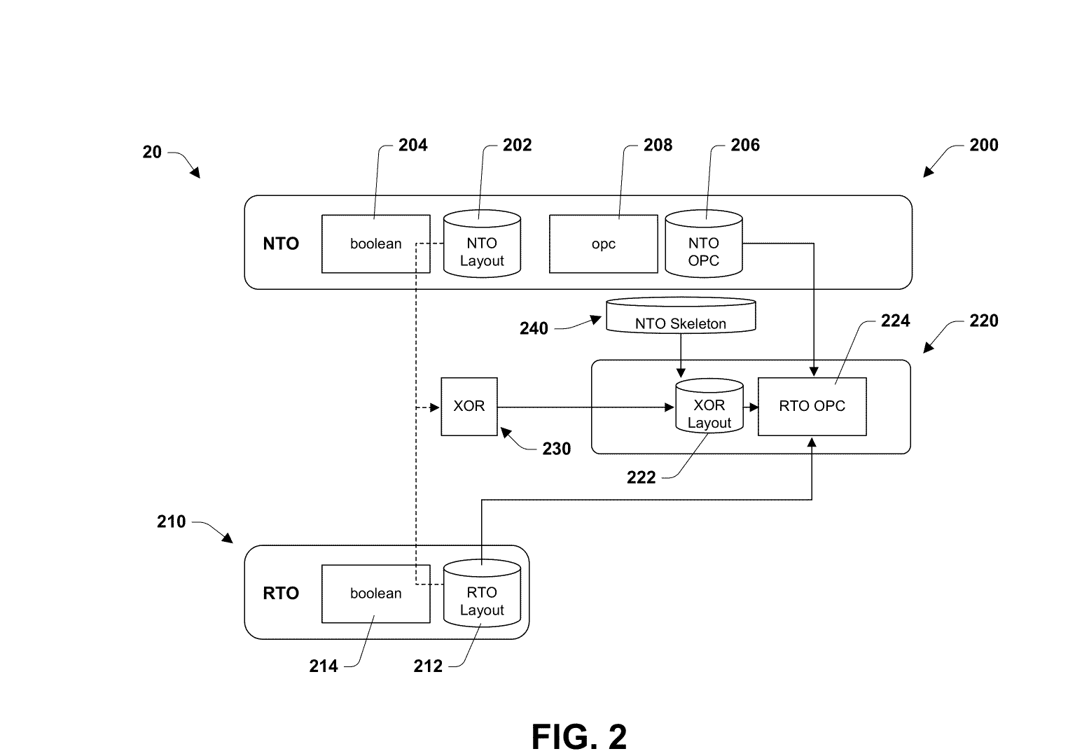

Generally, for an NTO layout, the OPC may be performed first on all correction regions 1520 having the first sequence value “0,” then on all correction regions 1520 having the second sequence value “1,” then on all correction regions 1520 having the third sequence value “2,” then on all correction regions 1520 having the fourth sequence value “3.” For an RTO layout based on an NTO layout that has already been corrected, performing OPC on the entire RTO layout can be time-consuming and power-consuming and can increase degradation of smallest-dimension feature uniformity (CDU). In embodiments of the disclosure, the RTO layout can be compared with the NTO layout to determine change regions associated with differences between the RTO layout and the NTO layout. Then, the change regions can undergo OPC to generate corrected change regions. The optically-corrected RTO layout can then include the corrected change regions and corrected regions of the NTO layout. Due to the OPC sequence by correction regions 1520 described above, when a change region has, for example, the first sequence value “0,” correction regions 1520 immediately adjacent to the change region are “affected regions.” In some embodiments, the affected regions undergo OPC to generate corrected affected regions. The optically-corrected RTO layout can then include the corrected change regions, the corrected affected regions and corrected regions of the NTO layout. Embodiments of performing OPC of the RTO layout based on the change regions and the affected regions are described with reference to FIGS. 2A-2E.

FIG. 2 illustrates a diagrammatic view of a method 20 of performing OPC, in accordance with some embodiments.

The method 20 includes NTO operations 200, RTO operations 210, and selective RTO OPC generation operations 220. In some embodiments, some or all of the method 20 is performed by an electronic design automation (EDA) system.

In FIG. 2, the method 20 includes receiving first circuit layout data from a first database 202. In some embodiments, the first circuit layout data includes NTO layout data. In some embodiments, the first circuit layout data is or includes an Open Artwork System Interchange Standard (OASIS) file, a Graphic Design System II (GDSII) file, or the like. In some embodiments, the first circuit layout data includes prior RTO layout data. The first circuit layout data is stored in the first database 202.

The method 20 includes receiving second circuit layout data from a second database 212. In some embodiments, the second circuit layout data includes RTO layout data. In some embodiments, the second circuit layout data is or includes an OASIS file, a GDSII file, or the like. The second circuit layout data is stored in the second database 212. In some embodiments, the first database 202 and the second database 212 are the same database or are different databases than each other.

The method 20 includes determining unchanged regions and changed regions of the second circuit layout data. In some embodiments, the determining includes performing an exclusive-or (XOR) operation 230 on the first circuit layout data and the second circuit layout data. The XOR operation 230 can compare the first circuit layout data with the second circuit layout data to generate a comparison result.

The method 20 includes, based on the comparison result, generating comparison layout data (or “XOR layout”) stored in a fourth database 222. The comparison layout data can be or include an OASIS file, a GDSII file, or the like. In some embodiments, the comparison layout data includes or represents changed features and optionally unchanged features that are associated with the comparison result. For example, the comparison layout data may include positions (e.g., coordinates) associated with the changed features. In some embodiments, the fourth database 222 is the same database as or a different database than the first database 202, the second database 212, or both.

In some embodiments, prior to determining the unchanged regions and the changed regions of the second circuit layout data, the method 20 includes performing a first Boolean operation 204, a second Boolean operation 214 or both. The first Boolean operation 204 may be performed on the first circuit layout data, and the second Boolean operation 214 may be performed on the second circuit layout data. The first Boolean operation 204 and the second Boolean operation 214 can include one or more of a logical OR to merge overlaps or unionize shapes, a logical NOT to remove stray fragments, a logical AND trim overlaps or the like. Performing the first Boolean operation 204 and the second Boolean operation 214 can normalize geometries of both layouts, which can be beneficial to reduce false positives during generation of the comparison layout data.

The method 20 includes generating first optically-corrected layout data, which is stored in a third database 206. The first optically-corrected layout data may be generated by an OPC operation 208 that is performed on the first circuit layout data. In some embodiments, the third database 206 is the same database as or a different database than the first database 202, the second database 212, the fourth database 222, or a combination thereof.

The method 20 includes obtaining first OPC data associated with the unchanged features. In some embodiments, obtaining the first OPC data associated with the unchanged features includes obtaining first OPC data associated with the entire first circuit layout data (e.g., receiving an OASIS file containing OPC data for the entire first circuit layout data, such as the first optically-corrected layout data stored in the third database 206), then selecting portion(s) of the first OPC data associated with the unchanged features. For example, the selecting portion(s) can be performed based on the positions of the unchanged features indicated by the comparison layout data. In some embodiments, obtaining the first OPC data associated with the unchanged features includes determining positions of the unchanged features, then receiving only the portion(s) of the first circuit layout data that are optically-corrected and associated with the unchanged features. For example, the first OPC data associated with the unchanged features may be obtained from the first optically-corrected layout data that is stored in the third database 206.

The method 20 includes providing index/indices associated with the changed features. In some embodiments, providing the index or indices includes obtaining the index/indices (e.g., positions, coordinates, etc.) associated with the changed features from the comparison layout data.

The method 20 includes performing OPC on the changed features in the second circuit layout data obtained from the second database 212. For example, the second circuit layout data may be received from the second database 212, then optical proximity correction may be performed at positions of the second circuit layout data associated with the changed features as indicated by the comparison layout data. Second optically-corrected layout data can be generated by performing the OPC at the positions of the second circuit layout data associated with the changed features.

The method 20 includes generating a third circuit layout data 224 that includes the second optically-corrected layout data associated with the changed features and the first optically-corrected layout data associated with the unchanged features. The second optically-corrected layout data is generated based on the second circuit layout data and the first optically-corrected layout data is generated based on the first circuit layout data. Generally, the first optically-corrected layout data associated with the NTO is previously generated. Generating the second optically-corrected layout data associated with the changed features and omitting generation of optically-corrected layout data associated with the unchanged features reduces consumption of time and power resources and also reduces degradation of CDU of the layout data associated with the unchanged features.

In some embodiments, in addition to generating the second optically-corrected layout data associated with the changed features, the method 20 includes generating the second optically-corrected layout data associated with affected features or affected regions. For example, the method 20 can include determining OPC regeneration regions (e.g., the affected regions) associated with each corresponding index or position of the changed feature(s) by a first formula. In some embodiments, the first formula refers to a sequence of performing optical correction over a grid 240 of correction regions that can include first correction regions, second correction regions, third correction regions, and fourth correction regions. In some embodiments, number of types of correction regions can be four as described or can be fewer or greater than four, such as two, six, eight, or the like. The grid 240 can be received, for example, by a processor that executes instructions (e.g., the method 20) to generate the third circuit layout data.

The affected features or affected regions can be features or regions that are adjacent the changed features or changed regions that contain the changed features. The affected features or affected regions can be understood based on the method of performing OPC described with reference to FIG. 1C. Namely, the first circuit layout data and the second circuit layout data may each be associated with a grid of correction regions (e.g., the correction regions 1520). The correction regions may include first correction regions, second correction regions, third correction regions, and fourth corrections regions. OPC may be performed sequentially. For example, the first correction regions may be optically corrected without referring to others of the correction regions. Then, the second correction regions may be optically corrected with reference to the first correction regions. Then, the third correction regions may be optically corrected with reference to the first and second correction regions. Then, the fourth correction regions may be optically corrected with reference to the first, second and third correction regions.

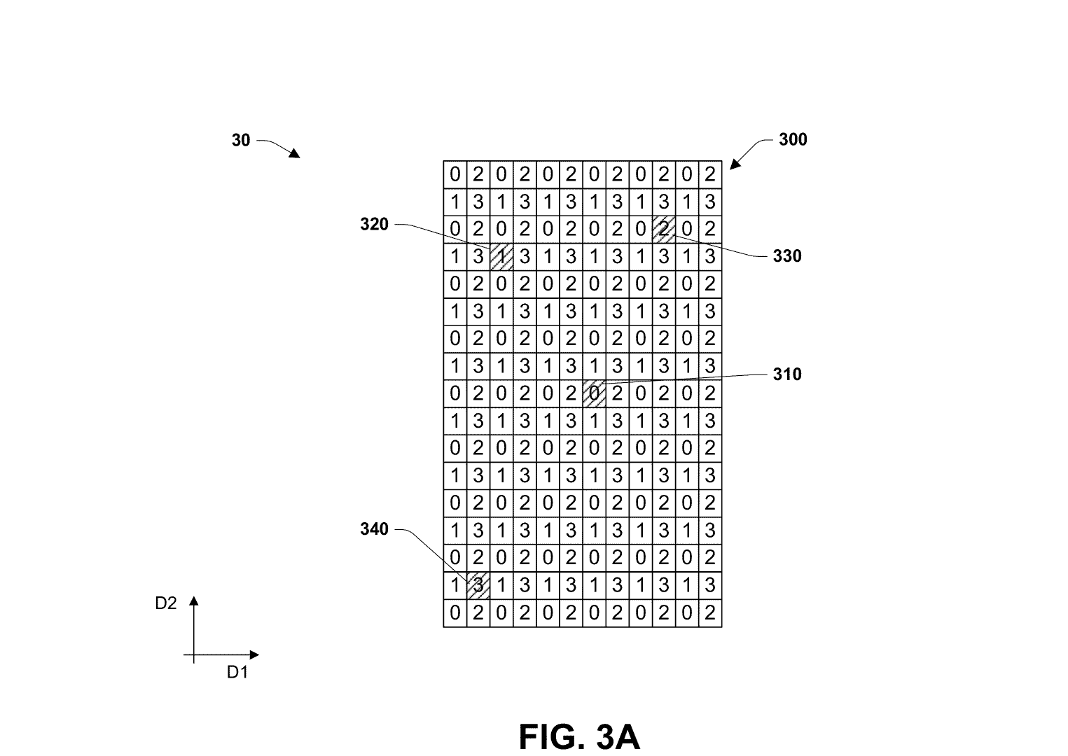

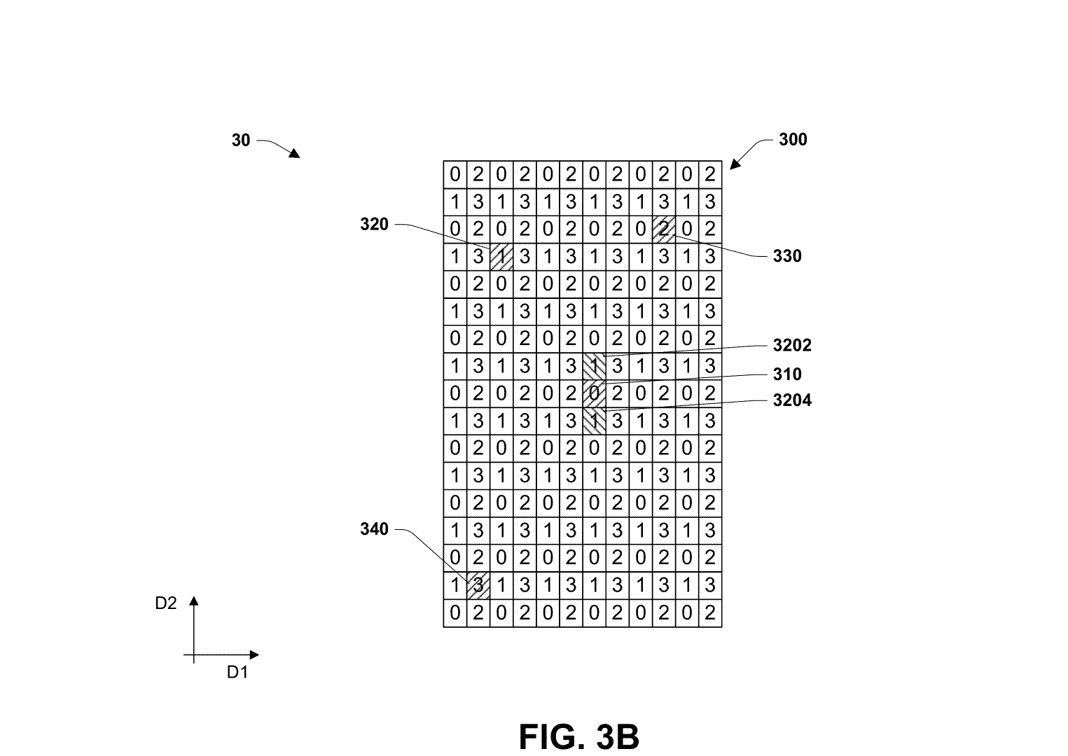

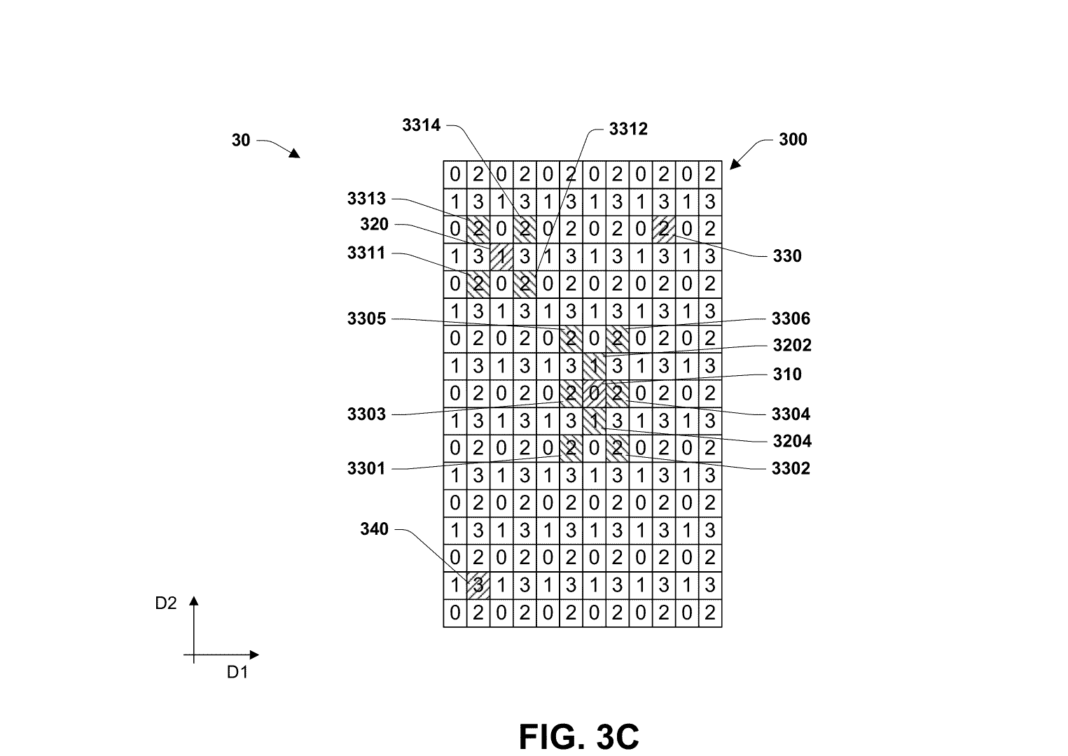

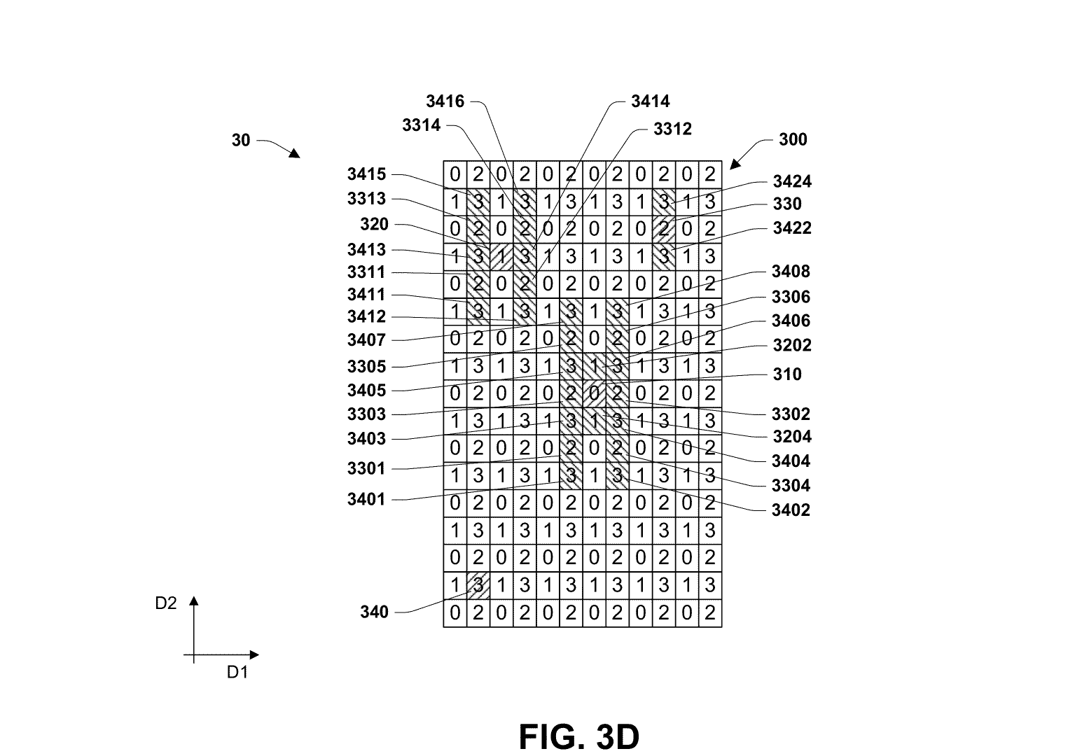

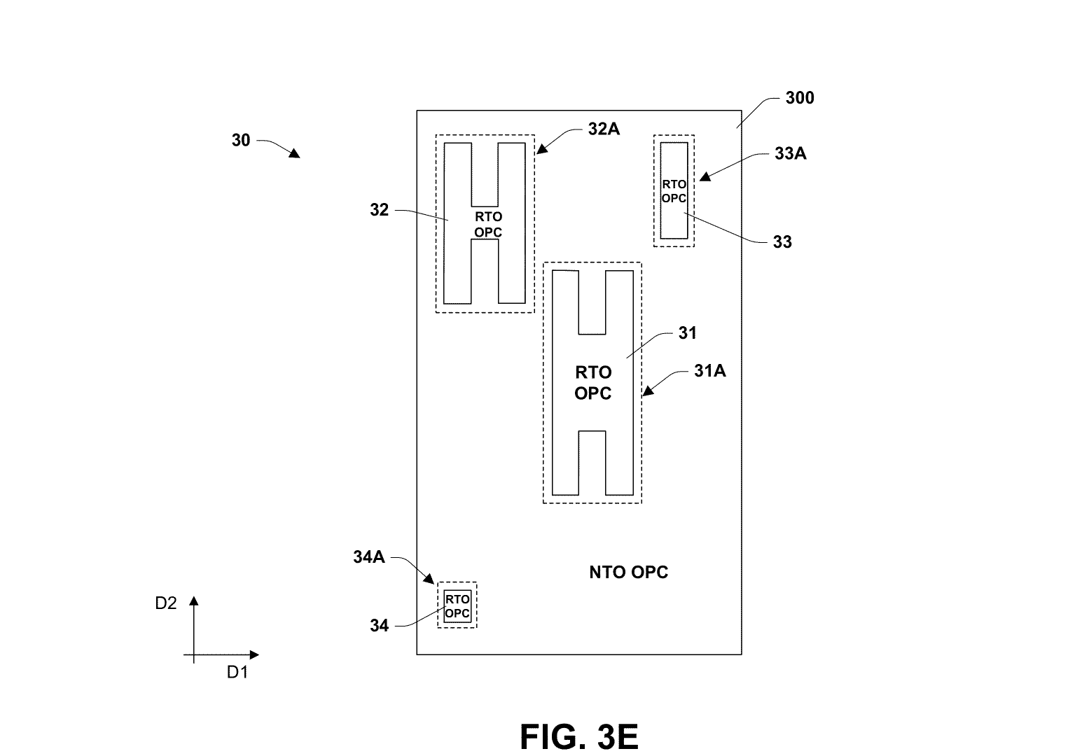

A changed feature of the changed features may be positioned in a first correction region. As a result, because second, third and fourth correction regions immediately adjacent thereto are optically corrected based on the first correction region, the second, third and fourth correction regions are considered “affected regions.” Embodiments of determining the affected regions are described with reference to FIGS. 3A-3E.

In some embodiments, the method 20 includes determining second optically-corrected layout data by performing an OPC regeneration operation on the affected regions based on a second formula. The second formula can refer to a shape that is associated with each changed region based on which type of correction region the changed region is. For example, the shape can be an enlarged H shape that is associated with the first correction region, an H shape that is associated with the second correction region, a line shape that is associated with the third correction region, or a point that is associated with the fourth correction region.

In some embodiments, the first formula and the second formula are stored in a database, which can be one or more of the first database 202, the second database 212, the third database 206, the fourth database 222, or another database other than the first database 202, the second database 212, the third database 206, and the fourth database 222.

In some embodiments, the method 20 includes generating the third circuit layout data 224 that includes the second optically-corrected layout data associated with the changed features and the affected features and the first optically-corrected layout data associated with the unchanged features.

Although not separately illustrated, the method 20 can include forming a mask based on the third circuit layout data 224. Then, the method 20 can include performing a photolithography operation by the mask. The photolithography operation can include exposing a photosensitive layer, such as a resist layer, by patterned light that is reflected by a pattern of the mask. The pattern of the mask can include first regions that are associated with unchanged regions of the second circuit layout data, such as first portions of the first optically-corrected layout data that correspond to the unchanged regions. The pattern of the mask can include second regions that are associated with changed regions of the second circuit layout data, such as second portions of the second optically-corrected layout data that correspond to the changed regions. In some embodiments, the pattern of the mask includes third regions that are associated with affected regions of the second circuit layout data, such as third portions of the second optically-corrected layout data that correspond to the affected regions. The method 20 can include etching a material layer under the resist layer through openings in the resist layer that are associated with the pattern of the mask. As such, the material layer can include first features associated with the first portions, second features associated with the second portions and optionally third features associated with the third portions. Namely, the material layer can include first features that are formed based on optically-corrected NTO layout data, second features that are formed based on optically-corrected RTO layout data and optionally third features that are formed based optically-corrected RTO layout data. Because the first features are formed based on the optically-corrected NTO layout data instead of on optically-corrected RTO layout data, the first features may have improved CDU.

FIGS. 3A, 3B, 3C, 3D, and 3E illustrate diagrammatic views of a method 30 of forming a mask that includes performing optical proximity correction (OPC), in accordance with some embodiments.

As described with reference to FIG. 2, the method 20 can include determining affected regions that are adjacent the changed regions.

In FIG. 3A, corresponding to determining the changed regions described with reference to FIG. 2, the method 30 includes determining a first changed region 310, a second changed region 320, a third changed region 330 and a fourth changed region 340, which are indicated by upward diagonal patterning in FIGS. 3A-3D. In some embodiments, unchanged regions 300 (indicated by no patterning) other than the first changed region 310, the second changed region 320, the third changed region 330 and the fourth changed region 340 are determined. The determining can be by performing an XOR operation on first circuit layout data and second circuit layout data, as described with reference to FIG. 2.

As depicted, the first changed region 310 can be a first correction region, which is indicated by “0” in FIG. 3A. The second changed region 320 can be a second correction region, which is indicated by “1” in FIG. 3A. The third changed region 330 can be a third correction region, which is indicated by “2” in FIG. 3A. The fourth changed region 340 can be a fourth correction region, which is indicated by “3” in FIG. 3A.

Initially, in FIG. 3A, first optically-corrected changed region data is generated by performing OPC on the first changed region 310 without referring to immediately adjacent correction regions. In the method 30, the OPC is performed on the first changed region 310 while omitting performing the OPC on other first correction regions that are unchanged regions 300. Omitting the unchanged regions 300 that are first corrections regions saves time and power resources and does not degrade CDU of the unchanged regions 300.

In FIG. 3B, following performing OPC on the first changed region 310, second optically-corrected changed region data is generated by performing OPC on the second changed region 320 and second optically-corrected affected region data is generated by performing OPC on second affected regions 3202, 3204, which are second correction regions. The second affected region 3202 is above the first changed region 310 along a second direction D2. The second affected region 3204 is below the first changed region 310 along the second direction D2. OPC is performed on the second affected regions 3202, 3204 due to OPC of the first changed region 310 being different than OPC of a corresponding first changed region in the first circuit layout data (e.g., NTO layout data). Namely, it can be beneficial, instead of copying the optically-corrected data associated with the second affected regions 3202, 3204 from the first optically-corrected layout data (e.g., the NTO layout data), to regenerate optically-corrected data associated with the second affected regions 3202, 3204 based on the first optically-corrected changed region data associated with the first changed region 310.

In FIG. 3C, following performing OPC on the second changed region 320 and the second affected regions 3202, 3204, third optically-corrected changed region data is generated by performing OPC on the third changed region 330 and third optically-corrected affected region data is generated by performing OPC on third affected regions 3301, 3302, 3303, 3304, 3305, 3306, 3311, 3312, 3313, 3314, which are third correction regions. The third affected regions 3301, 3302, 3303, 3304 are positioned at immediately adjacent corners of the second affected region 3204. The third affected regions 3303, 3304, 3305, 3306 are positioned at immediately adjacent corners of the second affected region 3202. The third affected regions 3311, 3312, 3313, 3314 are positioned at immediately adjacent corners of the second changed region 320.

OPC is performed on the third affected regions 3301, 3302, 3303, 3304, 3305, 3306, 3311, 3312, 3313, 3314 due to OPC of the second changed region 320 and the second affected regions 3202, 3204 being different than OPC of the corresponding second changed region and second affected regions in the first circuit layout data (e.g., NTO layout data). Namely, it can be beneficial, instead of copying the optically-corrected data associated with the third affected regions 3301, 3302, 3303, 3304, 3305, 3306, 3311, 3312, 3313, 3314 from the first optically-corrected layout data (e.g., the NTO layout data), to regenerate optically-corrected data associated with the third affected regions 3301, 3302, 3303, 3304, 3305, 3306, 3311, 3312, 3313, 3314 based on the first optically-corrected changed region data associated with the first changed region 310 and the second optically-corrected changed and affected region data associated with the second changed region 320 and the second affected regions 3202, 3204.

In FIG. 3D, following performing OPC on the third changed region 330 and the third affected regions 3301, 3302, 3303, 3304, 3305, 3306, 3311, 3312, 3313, 3314, fourth optically-corrected changed region data is generated by performing OPC on the fourth changed region 340 and fourth optically-corrected affected region data is generated by performing OPC on fourth affected regions 3401, 3402, 3403, 3404, 3405, 3406, 3407, 3408, 3411, 3412, 3413, 3414, 3415, 3416, 3422, 3424, which are fourth correction regions. The fourth affected regions 3401, 3402, 3403, 3404, 3405, 3406, 3407, 3408 are positioned immediately adjacent the third affected regions 3301, 3302, 3303, 3304, 3305, 3306 along the second direction D2. The fourth affected regions 3411, 3412, 3413, 3414, 3415, 3416 are positioned immediately adjacent the third affected regions 3311, 3312, 3313, 3314 along the second direction D2. The fourth affected regions 3422, 3424 are positioned immediately adjacent the third changed region 330 along the second direction D2.

OPC is performed on the fourth affected regions 3401, 3402, 3403, 3404, 3405, 3406, 3407, 3408, 3411, 3412, 3413, 3414, 3415, 3416, 3422, 3424 due to OPC of the third changed region 330 and the third affected regions 3301, 3302, 3303, 3304, 3305, 3306, 3311, 3312, 3313, 3314 being different than OPC of the corresponding third changed region and third affected regions in the first circuit layout data (e.g., NTO layout data). Namely, it can be beneficial, instead of copying the optically-corrected data associated with the fourth affected regions 3401, 3402, 3403, 3404, 3405, 3406, 3407, 3408, 3411, 3412, 3413, 3414, 3415, 3416, 3422, 3424 from the first optically-corrected layout data (e.g., the NTO layout data), to regenerate optically-corrected data associated with the fourth affected regions 3401, 3402, 3403, 3404, 3405, 3406, 3407, 3408, 3411, 3412, 3413, 3414, 3415, 3416, 3422, 3424 based on the first optically-corrected changed region data associated with the first changed region 310, the second optically-corrected changed and affected region data associated with the second changed region 320 and the second affected regions 3202, 3204, and the third optically-corrected changed and affected region data associated with the third changed region 330 and the third affected regions 3301, 3302, 3303, 3304, 3305, 3306, 3311, 3312, 3313, 3314.

Following the operations described with reference to FIGS. 3A-3D, third circuit layout data (e.g., the third circuit layout data 224) is depicted in FIG. 3D. For example, the third circuit layout data includes optically-corrected NTO layout data in the unchanged regions 300 and optically-corrected RTO layout data in the first changed region 310, the second changed region 320, the third changed region 330, the fourth changed region 340, the second affected regions 3202, 3204, the third affected regions 3301, 3302, 3303, 3304, 3305, 3306, 3311, 3312, 3313, 3314 and the fourth affected regions 3401, 3402, 3403, 3404, 3405, 3406, 3407, 3408, 3411, 3412, 3413, 3414, 3415, 3416, 3422, 3424.

In some embodiments, as described, determining a changed region of the second circuit layout data (e.g., from the RTO layout) includes comparing the second circuit layout data with the first circuit layout data (e.g., from the NTO layout). Then, a plurality of affected regions are determined to be associated with the changed region, such as the first changed region 310, the second changed region 320, the third changed region 330, the fourth changed region 340 or the like. In some embodiments, the process includes determining whether the changed region is associated with the first correction regions, the second correction regions, the third correction regions, or the fourth correction regions. Then, in response to the changed region being associated with the first correction regions, the process includes determining the plurality of affected regions including two of the second correction regions, six of the third correction regions and eight of the fourth correction regions. Or, in response to the changed region being associated with the second correction regions, the process includes determining the plurality of affected regions including four of the third correction regions and six of the fourth correction regions. Or, in response to the changed region being associated with the third correction regions, the process includes determining the plurality of affected regions including two of the fourth correction regions.

FIG. 3E illustrates a simplified diagrammatic view of third circuit layout data (e.g., the third circuit layout data 224), in accordance with some embodiments.

The third circuit layout data includes optically-corrected RTO layout data in a first OPC region 31, a second OPC region 32, a third OPC region 33 and a fourth OPC region 34. The third circuit layout data includes optically-corrected NTO layout data and/or optically-corrected prior RTO layout data in the unchanged regions 300.

The first OPC region 31 includes optically-corrected RTO layout data associated with the first changed region 310, the second affected regions 3202, 3204, the third affected regions 3301, 3302, 3303, 3304, 3305, 3306 and the fourth affected regions 3401, 3402, 3403, 3404, 3405, 3406, 3407, 3408. The first OPC region 31 has an enlarged H shape.

The second OPC region 32 includes optically-corrected RTO layout data associated with the second changed region 320, the third affected regions 3311, 3312, 3313, 3314 and the fourth affected regions 3411, 3412, 3413, 3414, 3415, 3416. The second OPC region 32 has an H shape.

The third OPC region 33 includes optically-corrected RTO layout data associated with the third changed region 330 and the fourth affected regions 3422, 3424. The third OPC region 33 has a line shape.

The fourth OPC region 34 includes optically-corrected RTO layout data associated with the fourth changed region 340. The fourth OPC region 34 has a point or dot shape.

FIG. 3E also illustrates a first data region 31A, a second data region 32A, a third data region 33A, and a fourth data region 34A.

The first data region 31A surrounds the first OPC region 31. As discussed with reference to FIG. 1C, the second correction regions are optically corrected with reference to the first correction regions. Prior to correcting the second correction regions, optically-corrected NTO layout data can be obtained that is associated with the first data region 31A. Then, for example, the second optically-corrected layout data associated with the second affected regions 3202, 3204 can be generated based on the first optically-corrected layout data associated with the first changed region 310 and optically-corrected NTO layout data associated with first correction regions positioned in the first data region 31A.

The second data region 32A surrounds the second OPC region 32. As discussed with reference to FIG. 1C, the third correction regions are optically corrected with reference to the first and second correction regions. Prior to correcting the third correction regions, optically-corrected NTO layout data can be obtained that is associated with the second data region 32A. Then, for example, the third optically-corrected layout data associated with the third affected regions 3311, 3312, 3313, 3314 can be generated based on the second optically-corrected layout data associated with the second changed region 320 and the optically-corrected NTO layout data associated with the first correction regions and the second correction regions positioned in the second data region 32A.

The third data region 33A surrounds the third OPC region 33. As discussed with reference to FIG. 1C, the fourth correction regions are optically corrected with reference to the first, second and third correction regions. Prior to correcting the fourth correction regions, optically-corrected NTO layout data can be obtained that is associated with the third data region 33A. Then, for example, the fourth optically-corrected layout data associated with the fourth affected regions 3422, 3424 can be generated based on the third optically-corrected layout data associated with the third changed region 330 and the optically-corrected NTO layout data associated with the first correction regions, the second correction regions and the third correction regions positioned in the third data region 33A.

The fourth data region 34A surrounds the fourth OPC region 34. As discussed with reference to FIG. 1C, the fourth correction regions are optically corrected with reference to the first, second and third correction regions. Prior to correcting the fourth correction regions, optically-corrected NTO layout data can be obtained that is associated with the fourth data region 34A. Then, the fourth optically-corrected layout data associated with the fourth changed region 340 can be generated based on the optically-corrected NTO layout data associated with the first correction regions, the second correction regions and the third correction regions positioned in the fourth data region 34A.

The description with reference to FIGS. 3A-3E includes changed regions that include the first changed region 310, the second changed region 320, the third changed region 330, and the fourth changed region 340. Each of the changed regions is a different type of correction region (e.g., first correction region, second correction region, etc.) and the affected regions associated therewith do not overlap with each other. It should be understood that the method 30 described with reference to FIGS. 3A-3E can also be performed with overlapping affected regions. Namely, regeneration of OPC data associated with the affected regions is not limited to situations in which the affected regions do not overlap each other.

The embodiments described with reference to FIGS. 3A-3E can be combined with those described with reference to FIGS. 1A, 1B, 1C and 2.

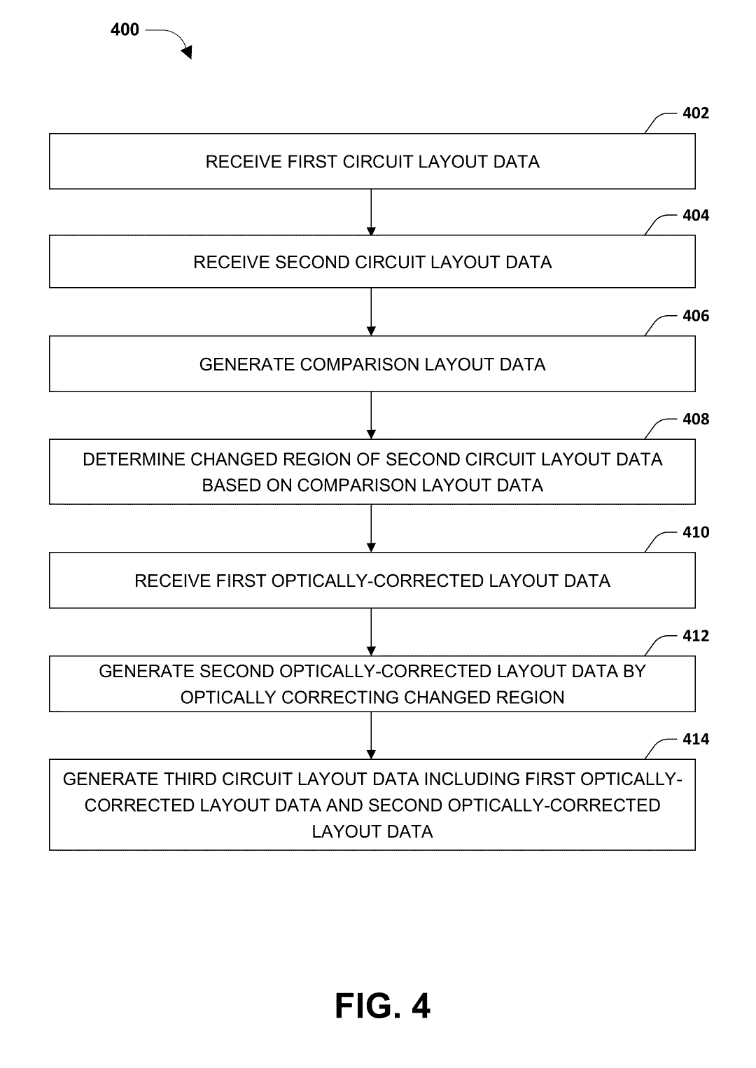

The method 400 is illustrated in FIG. 4 in accordance with some embodiments.

At 402, the method 400 includes receiving first circuit layout data associated with a material layer of an integrated circuit (IC) device.

At 404, the method 400 includes receiving second circuit layout data associated with the material layer.

At 406, the method 400 includes generating comparison layout data by performing a logical operation on the first circuit layout data and the second circuit layout data.

At 408, the method 400 includes determining a changed region of the second circuit layout data based on the comparison layout data.

At 410, the method 400 includes receiving first optically-corrected layout data associated with the first circuit layout data.

At 412, the method 400 includes generating second optically-corrected layout data by optically correcting the changed region.

At 414, the method 400 includes generating third circuit layout data including the first optically-corrected layout data and the second optically-corrected layout data.

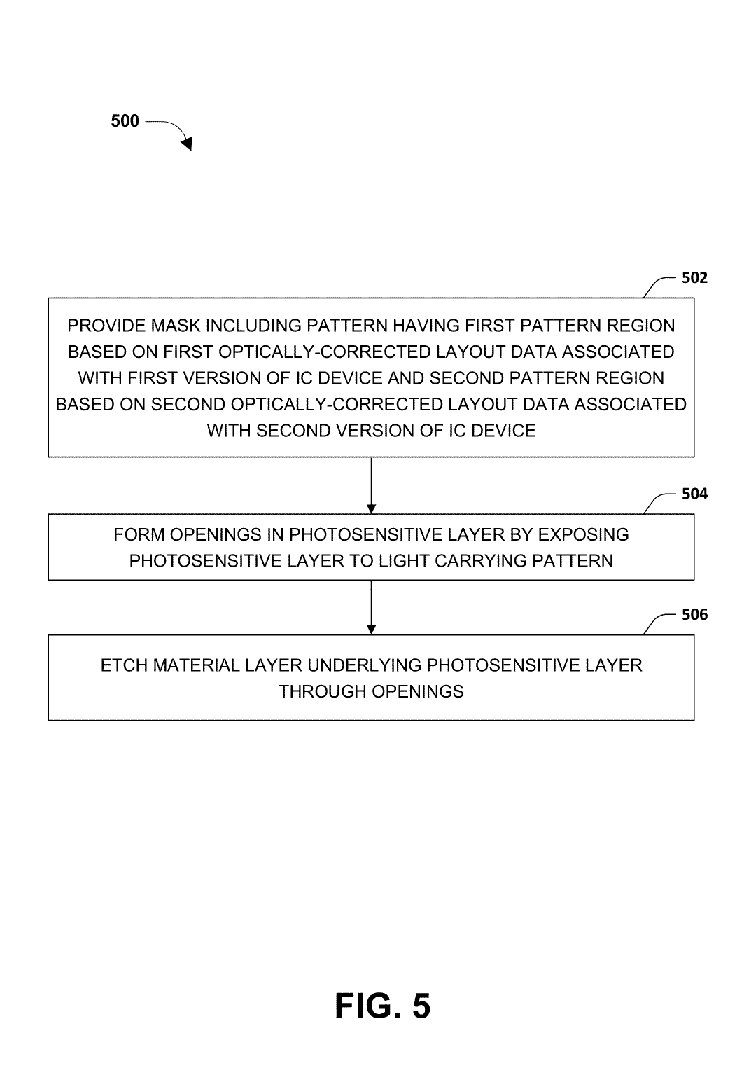

A method 500 is illustrated in FIG. 5 in accordance with some embodiments.

At 502, the method 500 includes providing a mask. The mask includes a pattern having a first pattern region and a second pattern region. The first pattern region is based on first optically-corrected layout data associated with a first version of an integrated circuit (IC) device. The second pattern region is based on second optically-corrected layout data associated with a second version of the IC device that is different than the first version.

At 504, the method 500 includes forming openings in a photosensitive layer by exposing the photosensitive layer to light carrying the pattern.

At 506, the method 500 includes etching a material layer underlying the photosensitive layer through the openings.

While methods 20, 30, 400, 500 are illustrated and described as series of acts or events, it will be appreciated that the illustrated ordering of such acts or events is not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases. As one non-limiting example, 402 and 404 of the method 400 can be performed simultaneously or in different order than that described with reference to FIG. 4.

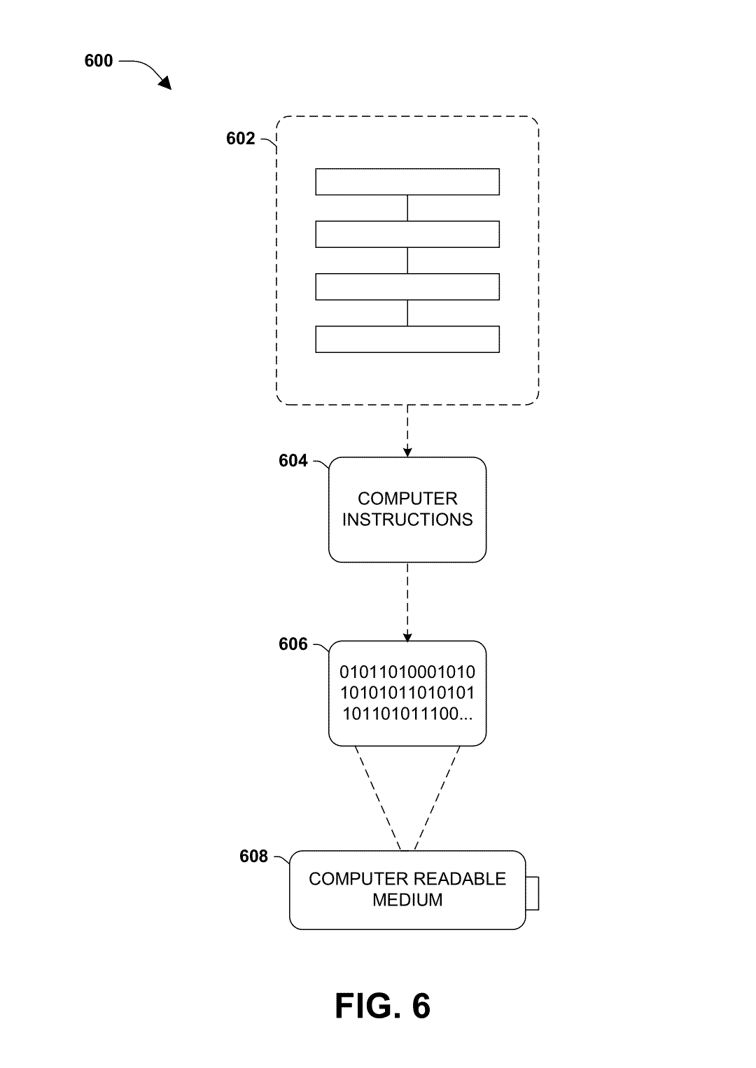

One or more embodiments involve a computer-readable medium comprising processor-executable instructions configured to implement one or more of the techniques presented herein. An exemplary computer-readable medium is illustrated in FIG. 6, wherein the embodiment 600 comprises a computer-readable medium 608 (e.g., a CD-R, DVD-R, flash drive, a platter of a hard disk drive, etc.), on which is encoded computer-readable data 606. This computer-readable data 606 in turn comprises a set of processor-executable computer instructions 604 configured to implement one or more of the principles set forth herein when executed by a processor. In some embodiments 600, the processor-executable computer instructions 604 are configured to implement a method 602, such as at least some of the aforementioned method(s) when executed by a processor. In some embodiments, the processor-executable computer instructions 604 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a method is provided. The method includes: receiving first circuit layout data associated with a material layer of an integrated circuit (IC) device; receiving second circuit layout data associated with the material layer; generating comparison layout data by performing a logical operation on the first circuit layout data and the second circuit layout data; determining a changed region of the second circuit layout data based on the comparison layout data; receiving first optically-corrected layout data associated with the first circuit layout data; generating second optically-corrected layout data by optically correcting the changed region; and generating third circuit layout data including the first optically-corrected layout data and the second optically-corrected layout data.

In some embodiments, a method is provided. The method includes: providing a mask, the mask including a pattern having a first pattern region and a second pattern region, the first pattern region being based on first optically-corrected layout data associated with a first version of an IC device, the second pattern region being based on second optically-corrected layout data associated with a second version of the IC device that is different than the first version; forming openings in a photosensitive layer by exposing the photosensitive layer to light carrying the pattern; and etching a material layer underlying the photosensitive layer through the openings.

In some embodiments, a system is provided. The system includes: a first database that stores first circuit layout data; a second database that stores second circuit layout data; and a processor configured to execute instructions. The instructions, when executed by the processor, configure the processor to: obtain the first circuit layout data; obtain first optically-corrected layout data associated with the first circuit layout data; obtain the second circuit layout data; determine a changed region of the second circuit layout data by comparing the second circuit layout data with the first circuit layout data; generate second optically-corrected layout data associated with the changed region; and generate third circuit layout data by replacing a portion of the first optically-corrected layout data associated with the changed region with the second optically-corrected layout data.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, "exemplary" and/or the like is used herein to mean serving as an example, instance, illustration, etc., and not necessarily as advantageous. As used in this application, "or" is intended to mean an inclusive "or" rather than an exclusive "or". In addition, "a" and "an" as used in this application and the appended claims are generally be construed to mean "one or more" unless specified otherwise or clear from context to be directed to a singular form. Also, at least one of A and B and/or the like generally means A or B or both A and B. Furthermore, to the extent that "includes", "having", "has", "with", or variants thereof are used, such terms are intended to be inclusive in a manner similar to the term "comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
receiving first circuit layout data associated with a material layer of an integrated circuit (IC) device;
receiving second circuit layout data associated with the material layer;
generating comparison layout data by performing a logical operation on the first circuit layout data and the second circuit layout data;
determining a changed region of the second circuit layout data based on the comparison layout data;
receiving first optically-corrected layout data associated with the first circuit layout data;
generating second optically-corrected layout data by optically correcting the changed region; and
generating third circuit layout data including the first optically-corrected layout data and the second optically-corrected layout data.

2. The method of claim 1, wherein performing the logical operation includes:
performing an XOR logical operation on the first circuit layout data and the second circuit layout data.

3. The method of claim 1, further comprising, prior to performing the logical operation:
performing a first Boolean operation on the first circuit layout data; and
performing a second Boolean operation on the second circuit layout data.

4. The method of claim 1, wherein generating the third circuit layout data includes:
replacing a portion of the first optically-corrected layout data associated with the changed region with the second optically-corrected layout data.

5. The method of claim 4, wherein generating the third circuit layout data includes:
removing the portion of the first optically-corrected layout data associated with the changed region; and
inserting the second optically-corrected layout data into the first optically-corrected layout data at a position of the portion.

6. A method comprising:
providing a mask, the mask including a pattern having a first pattern region and a second pattern region, the first pattern region being based on first optically-corrected layout data associated with a first version of an integrated circuit (IC) device, the second pattern region being based on second optically-corrected layout data associated with a second version of the IC device that is different than the first version;
forming openings in a photosensitive layer by exposing the photosensitive layer to light carrying the pattern; and
etching a material layer underlying the photosensitive layer through the openings.

7. The method of claim 6, wherein providing the mask includes:
providing the mask including the second pattern region that is based on the second optically-corrected layout data that is associated with a changed region.

8. The method of claim 7, wherein providing the mask includes:
providing the mask including the second pattern region that is based on the second optically-corrected layout data that is associated with at least one first affected region immediately adjacent the changed region.

9. The method of claim 8, wherein providing the mask includes:
providing the mask including the second pattern region that is based on the second optically-corrected layout data that is associated with a second affected region immediately adjacent the at least one first affected region.

10. The method of claim 9, wherein providing the mask includes:
providing the mask including the second pattern region that is based on the second optically-corrected layout data that is associated with a third affected region immediately adjacent the second affected region.

11. The method of claim 8, wherein providing the mask includes:
providing the mask including the second pattern region that is based on the second optically-corrected layout data, the second pattern region having enlarged H shape associated with the changed region and the at least one first affected region.

12. The method of claim 8, wherein providing the mask includes:
providing the mask including the second pattern region that is based on the second optically-corrected layout data, the second pattern region having H shape associated with the changed region and the at least one first affected region.

13. The method of claim 8, wherein providing the mask includes:
providing the mask including the second pattern region that is based on the second optically-corrected layout data, the second pattern region having line shape associated with the changed region and the at least one first affected region.

14. A system, comprising:
a first database that stores first circuit layout data;
a second database that stores second circuit layout data; and
a processor configured to execute instructions, the instructions, when executed by the processor, configuring the processor to:
obtain the first circuit layout data;
obtain first optically-corrected layout data associated with the first circuit layout data;
obtain the second circuit layout data;
determine a changed region of the second circuit layout data by comparing the second circuit layout data with the first circuit layout data;
generate second optically-corrected layout data associated with the changed region; and
generate third circuit layout data by replacing a portion of the first optically-corrected layout data associated with the changed region with the second optically-corrected layout data.

15. The system of claim 14, wherein the instructions, when executed by the processor, configure the processor to generate the second optically-corrected layout data, including:
obtaining a grid of correction regions associated with the first optically-corrected layout data, the correction regions including first correction regions, second correction regions, third correction regions, and fourth correction regions.

16. The system of claim 15, wherein the instructions, when executed by the processor, configure the processor to:
determine a plurality of affected regions associated with the changed region.

17. The system of claim 16, wherein the instructions, when executed by the processor, configure the processor to determine the plurality of affected regions by:
determining whether the changed region is associated with the first correction regions, the second correction regions, the third correction regions, or the fourth correction regions;
in response to the changed region being associated with the first correction regions, determining the plurality of affected regions including two of the second correction regions, six of the third correction regions and eight of the fourth correction regions;
in response to the changed region being associated with the second correction regions, determining the plurality of affected regions including four of the third correction regions and six of the fourth correction regions; and
in response to the changed region being associated with the third correction regions, determining the plurality of affected regions including two of the fourth correction regions.

18. The system of claim 16, wherein the instructions, when executed by the processor, configure the processor to generate the second optically-corrected layout data by:
generating first optically-corrected changed region data by performing first optical proximity correction (OPC) on the changed region; and
generating second optically-corrected affected region data by performing second OPC on at least two of the plurality of affected regions based on the first optically-corrected changed region data.

19. The system of claim 18, wherein the instructions, when executed by the processor, configure the processor to generate the second optically-corrected layout data by:
generating third optically-corrected affected region data by performing second OPC on at least four of the plurality of affected regions adjacent to the at least two based on the first optically-corrected changed region data and the second optically-corrected affected region data.

20. The system of claim 19, wherein the instructions, when executed by the processor, configure the processor to generate the second optically-corrected layout data by:
generating fourth optically-corrected affected region data by performing third OPC on at least six of the plurality of affected regions adjacent to the at least two and the at least four based on the first optically-corrected changed region data, the second optically-corrected affected region data and the third optically-corrected affected region data.
